(19) United States
(12) Patent Application Publication
(10) Pub. No.: US 2006/0083076 A1
(43) Pub. Date: Apr. 20, 2006

(54) Data management apparatus

(75) Inventors: Motohiro Sakai, Kawasaki (JP); Kazuhiko Yamamoto, Kawasaki (JP)

Correspondence Address: STAAS & HALSEY LLP, SUITE 700, 1201 NEW YORK AVENUE, N.W., WASHINGTON, DC, 20005, US

(73) Assignee: Fujitsu Limited, Kawasaki (JP)

(21) Appl. No.: 11/052,769

(22) Filed: Feb. 9, 2005

(30) Foreign Application Priority Data
Oct. 15, 2004 (JP) 2004-301671

(51) Int. Cl. G11C 7/10

(52) U.S. Cl. 365/189.05

(57) ABSTRACT

A backup data storage control unit makes a write-once storage medium store by-generation backup data in order of generations. A generation identification data storage control unit makes a generation identification data of the backup data stored at a storage position right in front of the by-generation backup data in the storage medium.

### BACKGROUND OF THE INVENTION

1. Field of the Invention

The present invention relates to a data management technique and specifically to a technique relating to a generation management of backup files.

2. Description of the Related Art

A series of data handled by an information system are managed by being stored in a storage device. The three techniques for example have conventionally been used as ones for managing a large amount of data as follows:
(1) A RAID (Redundant Arrays of Inexpensive Disks) technology which combines a plurality of relatively inexpensive hard disk apparatuses for providing a large capacity logical disk while maintaining a high speed data access and a reliability of data maintenance.

(2) A multi-volume technology for managing as a large volume by a file system for use in a host server virtually concatenating a plurality of volumes in a storage device.

(3) An HSM (Hierarchical Storage Management) technology for enabling storage of data in an excessive capacity than a disk storage apparatus by hierarchically combining a disk storage apparatus capable of a high speed data access with a media library apparatus using a large capacity removable media such as a magnetic tape, and by moving data between these apparatuses as required.

Additionally, relating to the present invention, for instance, an invention disclosed by a Japanese patent laid-open application publication Hei 11-212844 is concerned with a magneto-optical disc library alleviating a process load implicated on the host system associated with a dualizing of data. Also for instance, another invention disclosed by a Japanese patent laid-open application publication 2000-172545 is a data storage apparatus for reducing the time for save and restoring of data by reducing the data amount to be saved in an external storage apparatus from a volatile memory. Furthermore for instance, yet another invention disclosed by a Japanese patent laid-open application publication 2000-322298 is a generation management system assuring a generation management by a generation management for a backup file while precluding a human judgment.

There are problems in the above described technologies as follows.

The RAID technology is faced by a high management cost in proportion with storage capacity since hard disk apparatuses are combined. Besides, a configuration by using only the RAID technology is met with a storage capacity limitation since the RAID technology limits the number of combined apparatuses in terms of its storage capacity and reliability.

The virtual volume management by using a file system naturally cannot spare a file system, hence unable to use in an application for accessing to a disc without a file system present.

The HSM technology has an advantage of being capable to manage a large amount of data with a reduced management cost. The HSM technology, however, has difficulty in handling data outside a file system. In addition, there is a problem of consuming the server resources by the server moving data between the hierarchies.

### SUMMARY OF THE INVENTION

The purpose of the present invention is for improving the performance of a data management apparatus, which is a hybrid data management apparatus having a high speed disk apparatus and a large capacity media library apparatus both built therein, recognized as a virtual storage apparatus being seen as a transparent storage space from the view point of a host system, transparent of existence of a removable media, while suppressing a resource consumption in the host system through an autonomous hierarchical storage management within the data management apparatus.

A data management apparatus as one aspect of the present invention is a data management apparatus for performing a generation management of backup data for a plurality of generations, comprising a backup data storage control unit for making a write-once storage medium store by-generation backup data in order of generations; and a generation identification data storage control unit for making an identification data stored for identifying a generation of the backup data at a storage position right in front of the by-generation backup data in the storage medium.

The data management apparatus makes it easily possible to read out just enough backup data up to an instructed generation from among those for a plurality of generations being stored in a storage medium through a use of the identification data when restoring by using the backup data up to the instructed generation.

Meanwhile, a data management apparatus as another aspect of the present invention is a data management apparatus for performing a hierarchical storage management by using a primary and secondary storage apparatuses, comprising a primary storage control unit for making the primary storage apparatus store data; an inspection sign generation unit for generating an inspection sign which confirms a consistency of data between the pre- and post-storing done by the primary storage unit; a primary read-out process unit for reading out data being stored in the primary storage apparatus thereof; and a secondary storage control unit for making the secondary storage apparatus store the data read out of the primary storage apparatus and the inspection sign.

The data management apparatus makes it easily possible to check a consistency of backup data by using an inspection sign when restoring the backup data stored in the secondary storage apparatus to the primary storage unit, thereby improving reliability of the restored data.

As described above, according to the present invention, reliability of a data management apparatus is improved by comprising a high speed disk apparatus and a high capacity removable media library apparatus both built therein and performing a hierarchical storage control autonomously within the apparatus.

### BRIEF DESCRIPTION OF THE DRAWINGS

The present invention will be more apparent from the following detailed description when the accompanying drawings are referenced to.

FIG. 1A shows a first fundamental configuration of data management apparatus for embodying the present invention;

FIG. 1B shows a second fundamental configuration of data management apparatus for embodying the present invention;

FIG. 2 shows a specific configuration of data management apparatus for embodying the present invention;

FIG. 3 shows how backup data by generation are stored on a magnetic tape;

FIG. 4 is a process flow chart for a backup processing;

FIG. 5 is a process flow chart for a restore processing;

FIG. 6 shows an embodiment of computer-readable storage medium being stored with a control program.

### DESCRIPTION OF THE PREFERRED EMBODIMENTS

An embodiment of the present invention is described as follows while referring to the accompanying drawings.

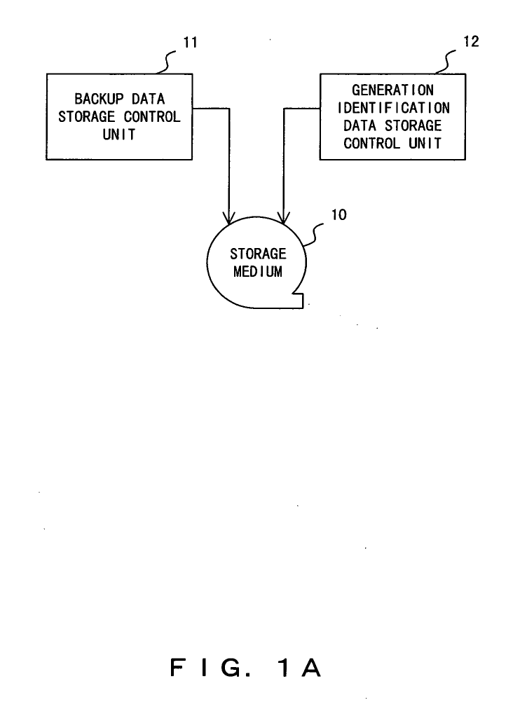

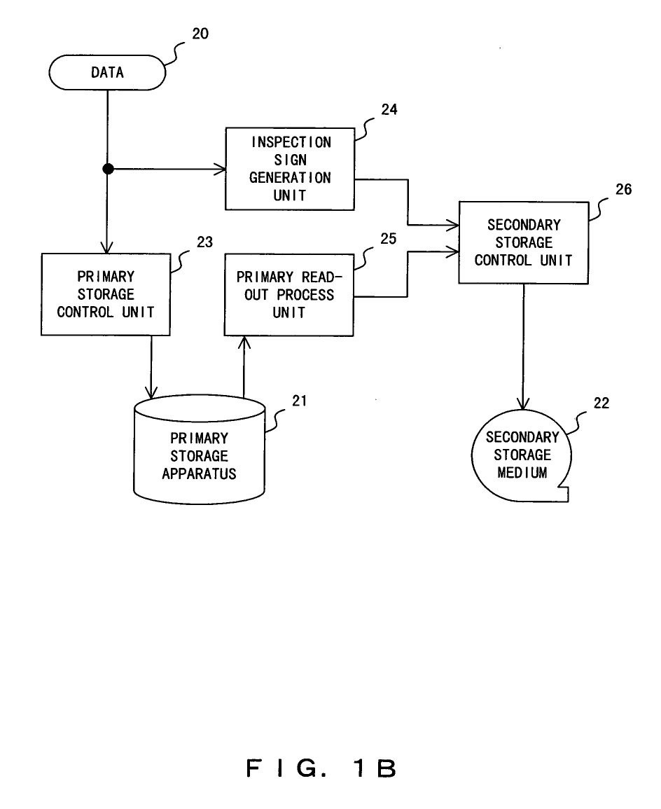

The first description is for FIG. 1A which shows a first fundamental configuration of data management apparatus for embodying the present invention. The data management apparatus is for a generation management of backup data for a plurality of generations.

A backup data storage control unit 11 makes a write-once storage medium 10 store by-generation backup data in order of generations.

A generation identification data storage control unit 12 makes an identification data stored for identifying a generation of the backup data at a storage position right in front of the above by-generation backup data in the storage medium 10.

This configuration makes it easily possible to read out just enough backup data up to a designated generation from among those for a plurality of generations being stored in the storage medium 10 through a use of the identification data when restoring by using the backup data up to the designated generation.

Meanwhile, the data management apparatus may be configured in which the storage medium 10 is a secondary storage in a hierarchical storage management that further comprises a primary storage unit for being a primary storage in a hierarchical storage management and storing data; a restore instruction acquisition unit for acquiring an instruction for restoring a backup data; a restore storage read-out process unit for reading the backup data out of the storage medium 10; a generation detection unit for detecting a generation of the backup data read out by the restore storage read-out process unit based on the above described identification data; and a restore storage control unit for making the backup data up to the designated generations stored in the primary storage unit from among the data read out by the restore storage read-out process unit.

This configuration makes it possible to easily restore just enough backup data up to a designated generation from among data for a plurality of generations being stored in the storage medium 10 through a use of the identification data when restoring the backup data stored in the storage medium 10 to the primary storage unit.

Meanwhile, the data management apparatus may further comprise a primary storage control unit for making by-generation backup data stored in the primary storage unit; an inspection sign generation unit for generating an inspection sign which confirms a consistency of backup data stored in the primary storage unit between the pre- and post-storing; and a transmission unit for reading out the backup data from the primary storage unit and transmitting the aforementioned data along with the inspection sign to the backup data storage control unit, wherein the backup data storage control unit makes the inspection sign stored in the storage medium along with the backup data transmitted by the transmission unit.

This configuration makes it possible to check a consistency of backup data by using an inspection sign when restoring the backup data stored in the storage medium 10 to the primary storage unit, thereby improving reliability of backup data after being restored.

Meanwhile, the data management apparatus may be configured, wherein the above described restore storage read-out process unit reads out the above described inspection sign along with the above described backup data, and the above described restore storage control unit confirms a consistency of the backup data based on the inspection sign when storing the backup data in the above described primary storage medium.

By this configuration, a consistency of the stored backup data is actually checked by using an inspection sign when restoring the backup data stored in the memory medium 10 to the primary storage unit.

The following is a description of FIG. 1B which shows a second fundamental configuration of data management apparatus for embodying the present invention. The data management apparatus is for performing a hierarchical storage management by using a primary and secondary storage apparatuses 21 and 22.

A primary storage control unit 23 makes data 20 stored in the primary storage apparatus 21.

An inspection sign generation unit 24 generates an inspection sign for confirming a consistency of the data 20 being stored in the primary storage apparatus 21 between the pre- and post-storing.

A primary read-out process unit 25 reads data being stored in the primary storage apparatus 21 out thereof.

A secondary storage control unit 26 makes the data read out of the primary storage apparatus 21 and the above described inspection sign stored in the secondary storage apparatus 22.

This configuration makes it possible to check a consistency of the backup data by using an inspection sign when restoring the backup data stored in the secondary storage apparatus 22 to the primary storage unit 21, thereby improving reliability of the restored data.

Meanwhile, the data management apparatus may further include a secondary read-out process unit for reading out data being stored in the secondary storage apparatus and, additionally, the above described inspection sign relating to the data, wherein the primary storage control unit confirms a consistency of the data based on the inspection sign read out by the secondary read-out process unit.

By this configuration, a consistency of stored backup data is actually checked by using an inspection sign when restoring the data stored in the secondary storage apparatus 22 into the primary storage apparatus 21.

Meanwhile, the data management method performed by a data management apparatus shown by FIG. 1A or FIG. 1B gains the same favorable performance result as the above described apparatuses. Furthermore, a program for making a computer operate the process performed by these apparatuses will obtain the same favorable performance result by the computer operating the program.

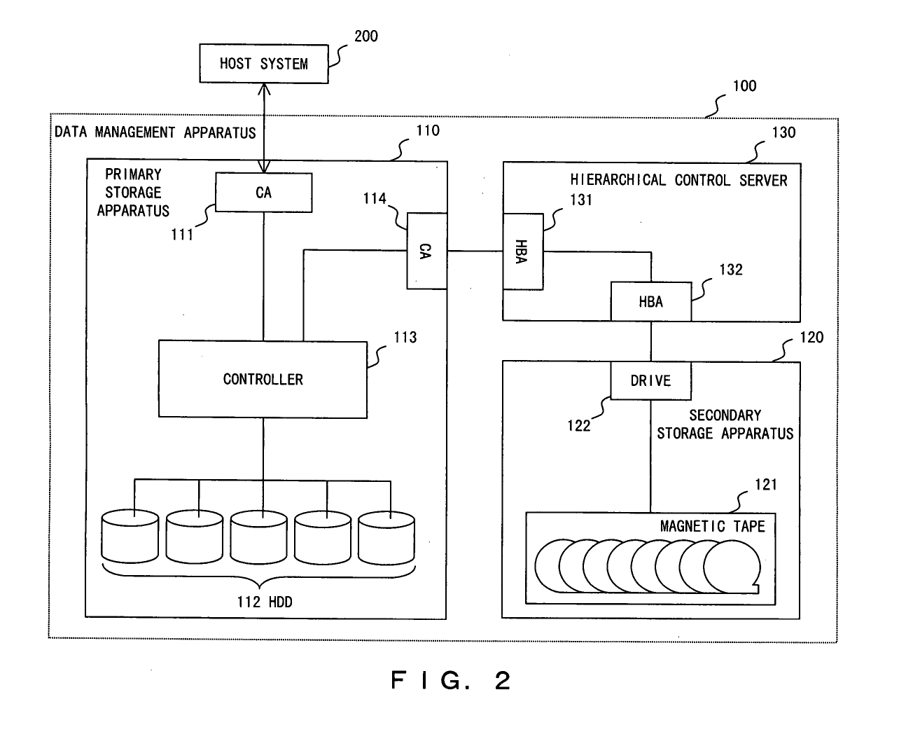

The following is a description of FIG. 2 which shows a specific configuration of data management apparatus for embodying the present invention.

A data management apparatus 100 stores backup data for a plurality of generations received from a host system 200, performs a generation management of the backup data and sends out the backup data to the host system 200 in accordance with an instruction thereof.

The data management apparatus 100 comprises a primary storage apparatus 110, a secondary storage apparatus 120 and a hierarchical control server 130 for performing a hierarchical storage management (HSM) for the aforementioned apparatuses.

A channel adaptor (CA) 111 equipped in the primary storage apparatus 110 manages data exchanges with the host system 200.

A hard disk drive (HDD) 112 is a data storage medium used as the primary storage in the HSM.

A controller 113 is for controlling data storage in the HDD 112 and makes the HDD 112 store data sent from the host system 200. Meanwhile, the controller 113 generates a check code (i.e., “inspection sign” noted in claims herein) for confirming a consistency of data between pre- and post-storing at a later time of reading out data when the controller 113 makes the HDD 112 store the data. Note that the inspection sign may adopt a block ID for indicating the storage location of stored data within the HDD 112, a cyclic redundancy check (CRC) code or a hamming code for example.

The CA 114 controls data exchanges with the hierarchical control server 130.

A magnetic tape 121 equipped in the secondary storage apparatus 120 is a write-once data storage medium used as the secondary storage for the HSM. Note that a write-once data storage medium may adopt a disk type data storage medium such as a CD or DVD in place of the magnetic tape 121.

A drive 122 controls storing data in the magnetic tape 121.

In the hierarchical control server 130, a host bus adaptor (HBA) 131 controls data exchanges with the primary storage apparatus 110, while the HBA 132 controls data exchanges with the secondary storage apparatus 120. The hierarchical control server 130 controls the operation of the secondary storage apparatus 120 in accordance with an instruction issued by the primary storage apparatus 110, thereby accomplishing the HSM in the data management apparatus 100.

It shall be noted that the hierarchical control server 130 includes a CPU, a ROM and a RAM (all not shown) therein, and the above described operation control is accomplished by making the CPU read out and operate a control program readily stored in the ROM. Meanwhile, the RAM provides a working storage area required for the CPU operating the control program.

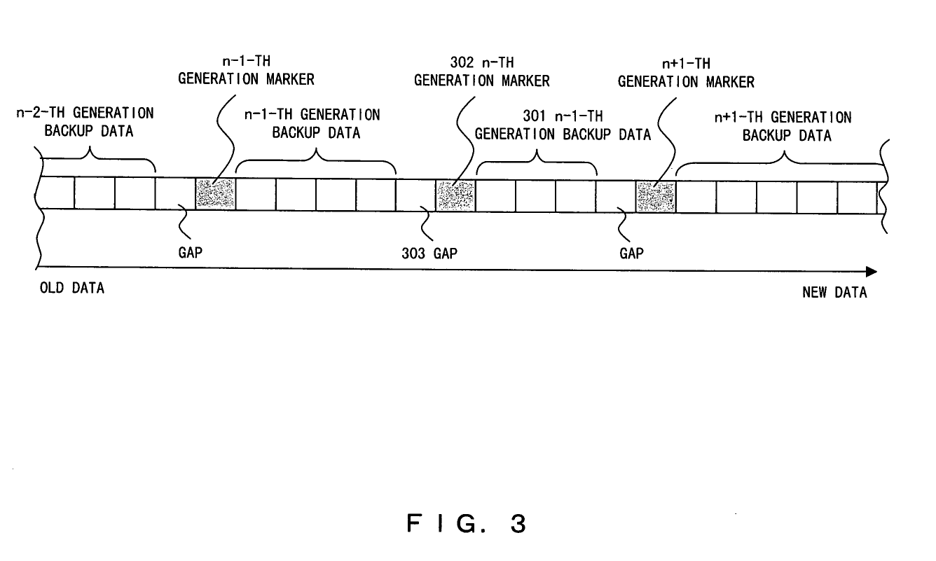

The following then is a description of FIG. 3 which shows how the backup data by generation are stored on a magnetic tape 121. FIG. 3 shows how the backup data for a plurality of generations are stored in order of generations ( . . . , the (n−1), n, (n+1) generations and so forth) in the magnetic tape 121, while an attention here is focused on the part of storage position for the backup data 301 of the n-th generation.

Right in front of the storage position of the backup data 301 is stored by a marker 302 which is a data indicating the generation of the backup data 301 (i.e., “generation identification data” noted in claims) of the n-th generation.

For instance, when the data management apparatus 100 receives an instruction from the host system 200 for restoring (“restore” noted in claims) a backup data with a generation being specified, the data up to the specified generation must be read out from among the backup data 301 stored in the magnetic tape 121 for a plurality of generations, in which case reading out the marker 302 makes it possible to read out the required backup data 301 just enough.

In addition, the marker 302 includes data relating to a corresponding backup data 301 such as the date of storing the backup data 301 in the magnetic tape 121.

Meanwhile, the storage position right in front of the marker 302 is located a gap 303 comprising at least a prescribed number of null data. The gap 303 is located for showing clearly the border between the backup data 301 and the marker 302 so as to enable a quick and easy detection of the marker 302 from the magnetic tape 121.

A series of control process performed in the data management apparatus 100 is then described.

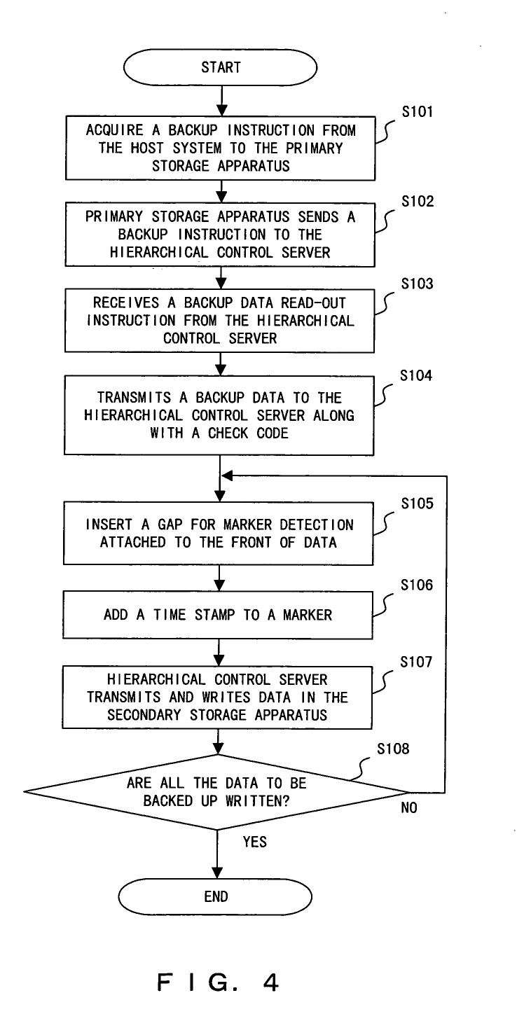

The following is a description of FIG. 4 which is a process flow chart for a backup processing. The processing is initiated by the host system 200 issuing instruction of a periodical data backup to the data management apparatus 100.

First in the step S101, the controller 113 equipped in the primary storage apparatus 110 detects the CA 111 acquiring a data backup instruction issued by the host system 200.

As the acquisition of the instruction is detected, the controller 113 sends the data backup instruction to the hierarchical control server 130 via the CA 111 in the step S102. Upon detecting a sign that the HBA 131 equipped in the hierarchical control server 130 has received the instruction, the hierarchical control server 130 enters a ready status for receiving a backup data 301 and accordingly the HBA 131 sends out a read-out instruction of a backup data 301 to the primary storage apparatus 110.

In the step S103, the controller 113 equipped in the primary storage apparatus 110 detects a receiving of the read-out instruction by a CA 114.

Upon detecting the receiving of the read-out instruction, the controller 113 controls the HDD 112 so as to read out the prior generation data stored therein and transmits the read-out data to the hierarchical control server 130 as the backup data 301 in the step S104. The above described check code, which is basically for confirming a consistency of data between pre- and post-storing in the HDD 112, is generated and transmitted to the hierarchical control server 130 along with the backup data 301.

The hierarchical control server 130 temporarily stores the backup data 301 and the check code transmitted from the primary storage apparatus 110 in the RAM equipped therein. Then, inserting the gap specified for the backup data 301 in front in the step S105, followed by inserting the marker 302 between the gap 303 and the backup data 301 in the step S106, are respectively done. Meanwhile, a generation identification data and a time stamp indicating the current date and time, both of the backup data 301, are included in the marker 302. Note that the time stamp itself may be used as a generation identification data.

Then, the hierarchical control server 130 makes the hierarchical control server 130 put together and transmit the gap 303, the marker 302, the backup data 301 and the check code by way of the HBA 132 to the secondary storage apparatus 120, followed by making the magnetic tape 121 store these data sequentially in the step S107.

At this point, the hierarchical control server 130 judges whether or not the backup data 301 up to the specified generation according to the instruction issued by the hierarchical control server 130 has been stored by writing in the magnetic tape 121. Here, if the writing is judged to be finished (i.e., the judgment result is “yes”), then the process shown by FIG. 4 is complete. Whereas if it is judged not to be finished (i.e., the judgment result is “no”), then the process goes back to the step S105 for repeating the above described processing.

Described above is the backup processing.

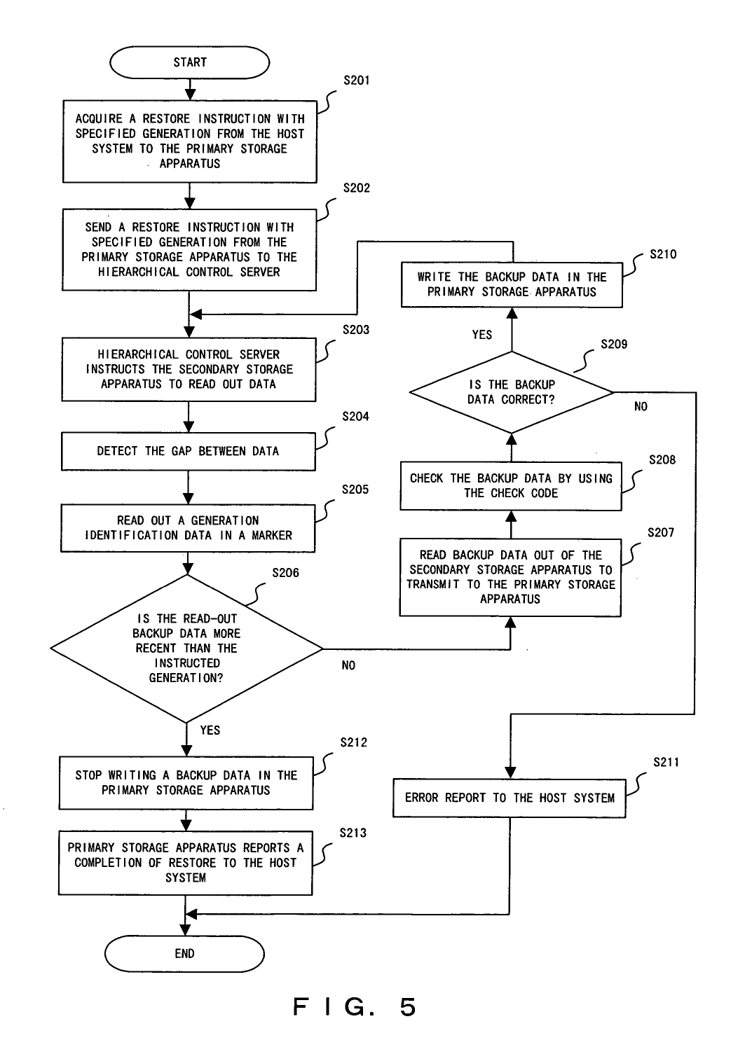

Then description goes to FIG. 5 which is a process flow chart for a restore processing. The processing is initiated by the host system 200 issuing an instruction to the data management apparatus 100 of restoring (restore) a backup data 301.

First in the step S201, the controller 113 equipped in the primary storage apparatus 110 detects the CA 111 acquiring a restore instruction for the backup data 301 issued by the host system 200.

As the acquisition of the instruction is detected, the controller 113 sends the restore instruction for the backup data 301 to the hierarchical control server 130 via the CA 114 in the step S202.

Upon detecting a sign that the HBA 131 equipped in the hierarchical control server 130 has received the instruction, the hierarchical control server 130 makes the HBA 132 send out a read-out instruction of the backup data 301 to the secondary storage apparatus 120 in the step S203. As the drive 122 equipped in the secondary storage apparatus 120 receives the read-out instruction, the drive 122 reads out stored data in the magnetic tape 121 from the top storage position of the data sequentially and transmits the read-out data to the hierarchical control server 130.

Having received the read-out data at the HBA 132, the hierarchical control server 130 first detects the gap 303 located between adjacent data in the step S204, and at this point, if a gap 303 is detected, then reads out a generation identification data included in the marker 302 which is positioned following the gap 303 in the step S205.

Here, the hierarchical control server 130 compares the generation indicated by the generation identification data read out in the previous step with the generation according to the restore instruction issued by the host system 200 to judge whether or not the generation of the data read out of the secondary storage apparatus 120 is more recent than that according to the aforementioned instruction in the step S206. Then, if the judgment is that the generation of the data read out in the processing is more recent than that according to the aforementioned instruction (i.e., judged to be “yes”), the step S212 follows. On the other hand, if the generation of the read-out data is no more recent (i.e., judged to be “no”) than that according to the aforementioned instruction, then the step S207 follows.

In the step S207, the hierarchical control server 130 controls the secondary storage apparatus 120 so as to make the latter read out of the magnetic tape 121 the backup data 301 of the generation corresponding to the marker 302 which has been referred to in the step S205 performed in the immediate past, and the check code, to transmit to the primary storage apparatus 110.

As the CA 114 receives the backup data 301 and the check code transmitted from the secondary storage apparatus 120 by way of the hierarchical control server 130, the controller 113 equipped in the primary storage apparatus 110 checks (i.e., confirms) a consistency of the backup data 301 by using the check code in the step S208. Then, as a result of the check, a judgment is made as to whether or not the backup data 301 is correct in the step S209 where, if the judgment is that the backup data 301 is correct (i.e., the judgment is “yes”), the processing goes to the step S210 in which the controller 113 controls the HDD 112 equipped in the primary storage apparatus 110 so as to perform a restoring of the backup data 301, that is, writing the backup data in the HDD 112. This is followed by going back to the step S203 and the above described processing of a backup data 301 for the subsequent generations will be repeated.

Contrarily, if the backup data 301 is judged to be incorrect (i.e., the judgment is “no”) in the step S209, the process goes to the step S211 in which the controller 113 makes the CA 111 report a processing error to the host system 200 and subsequently the processing shown by FIG. 5 is finished.

As described above, making the magnetic tape 121 store a check code generated by the controller 113 along with the backup data 301 and the controller 113 checking a consistency of the backup data 301 by using the check code at a time of data restoring make it possible to improve reliability of the backup data 301 in relation to transmitting backup data 301 between the primary storage apparatus 114 and the hierarchical control server 130 or the secondary storage apparatus 120 and to storing backup data 301 in the magnetic tape 121.

In the meantime, if the judgment in the above described step S206 is a “yes,” the controller 113 controls the HDD 112 so as to stop writing the backup data 301 therein in the step S212, and reports a completion of restoring the backup data 301 up to the instructed generation to the host system 200 by way of the CA 111 in the step S213. Subsequently the processing shown by FIG. 5 is finished.

Such is the restore processing. The processing performed by the data management apparatus 100 enables the backup data 301 up to the generation instructed by the host system 200 from among backup data 301 read out of the magnetic tape 121 of the secondary storage apparatus 120 to be stored in the HDD 112 of the primary storage apparatus 110.

Meanwhile, it is also possible to embody the present invention by making a computer of a standard configuration operate the processing flow charts shown by FIGS. 4 and 5 in a system having a storage apparatus for writing and reading data in and out of a write-once storage medium connected with the standard computer which comprises a CPU for controlling each component therein by operating a control program; a storage part comprising ROM, RAM, a magnetic storage apparatus, et cetera, and being used for storing control program that makes CPU control each component, a work area when the CPU execute the control program and a memory area for various data; an input part acquiring various data in relation to the user operation; an output part for providing various data for display, et cetera, for communicating with the user; and an interface (I/F) part for providing the interface functions for data exchanges with other equipment.

Accomplishing the above requires creating a control program for making a computer operate the processing shown by the flow charts in FIGS. 4 and 5, recording on a computer-readable storage medium and having a computer read the control program out of the medium to operate the program.

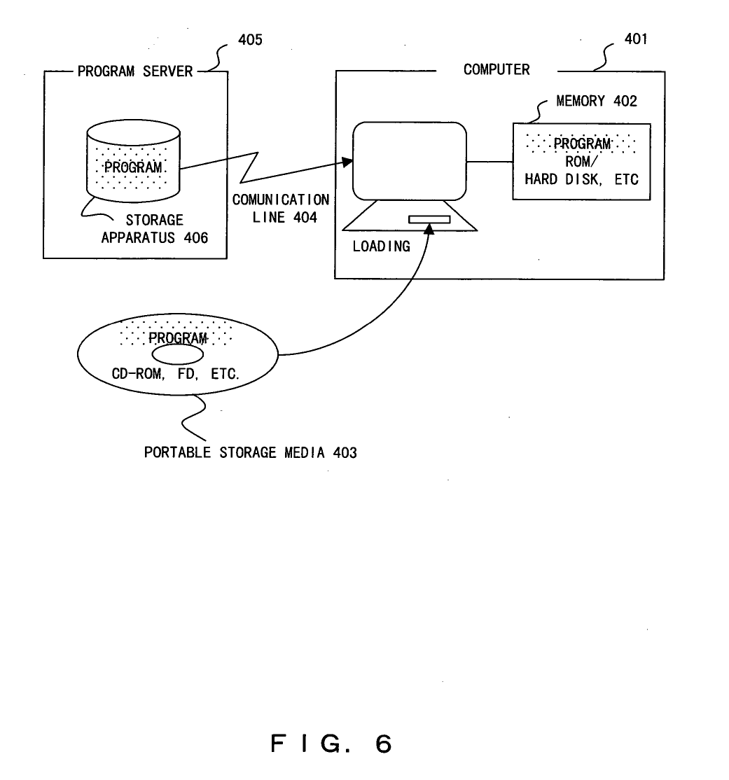

FIG. 6 shows an embodiment of computer-readable storage medium being stored with a control program. As shown in FIG. 6, the storage medium may adopt for example a memory 402 such as RAM, ROM or hard disk apparatus either built-in or externally equipped to a computer 401, or a portable storage medium 403 such as FD (flexible disk), MO (magneto-optical disk), CD-ROM, DVD-ROM, et cetera. Meanwhile, a storage medium may be a storage apparatus 406 equipped in a computer functioning as a program server 405 which is connected with the computer 401 through a communication line 404. In such case, the control program becomes operable by transmitting a transmission signal obtained by modulating a carrier wave with a data signal representing the control program from a program server 405 by way of a communication line 404 as a transmission medium, while by the computer 401 demodulating the received transmission signal and running the control program therein.

It shall be noted that the present invention is not limited to the above described embodiments but is possible to improve and change in various ways as appropriate.

What is claimed is:

1. A data management apparatus for performing a generation management of backup data for a plurality of generations, comprising:
a backup data storage control unit for making a write-once storage medium store by-generation backup data in order of generations; and
a generation identification data storage control unit for making an identification data stored for identifying a generation of the backup data at a storage position right in front of the by-generation backup data in the storage medium.

2. The apparatus in claim 1, wherein
said storage medium is a secondary storage in a hierarchical storage management, and
said data management apparatus further comprises:
a primary storage unit for being a primary storage in a hierarchical storage management and storing a data;
a restore instruction acquisition unit for acquiring an instruction for restoring a backup data;
a restore storage read-out process unit for reading the backup data out of the storage medium;
a generation detection unit for detecting a generation of backup data read out by the restore storage read-out process unit based on the identification data; and
a restore storage control unit for making the primary storage unit store backup data up to the designated generations from among the ones read out by the restore storage read-out process unit.

3. The apparatus in claim 2, further comprising:
a primary storage control unit for storing by-generation backup data in said primary storage unit;
an inspection sign generation unit for generating an inspection sign which confirms a consistency of backup data between the pre- and post-storing done by the primary storage unit; and
a transmission unit for reading out the backup data from the primary storage unit and transmitting the aforementioned data along with the inspection sign to said backup data storage control unit, wherein
the backup data storage control unit makes the inspection sign stored in said storage medium along with the backup data transmitted by the transmission unit.

4. The apparatus in claim 3, wherein
said restore storage read-out process unit reads out said inspection sign along with said backup data, and
said restore storage control unit confirms a consistency of the backup data based on the inspection sign when making said primary storage medium store the backup data therein.

5. A data management apparatus for performing a generation management of backup data for a plurality of generations, comprising:
backup data storage control means for making a write-once storage medium store by-generation backup data in order of generations; and
generation identification data storage control means for making an identification data stored for identifying a generation of the backup data at a storage position right in front of the by-generation backup data in the storage medium.

6. A data management apparatus for performing a generation management of backup data for a plurality of generations, comprising:
making by-generation backup data stored in a write-once storage medium in order of generations; and
making an identification data stored for identifying a generation of the backup data at a storage position right in front of the by-generation backup data in the storage medium.

7. A storage medium being stored with a program for making a computer perform a generation management of backup data for a plurality of generations, wherein, when executed by a computer, the program makes the computer perform the processes of:
making by-generation backup data stored in a write-once storage medium in order of generations; and
making an identification data stored for identifying a generation of the backup data at a storage position right in front of the by-generation backup data in the storage medium.

8. A computer data signal embodied in a carrier wave and representing a program for making a computer perform a generation management of backup data for a plurality of generations, wherein, when executed by a computer, the program makes the computer perform the processes of:
making by-generation backup data stored in a write-once storage medium in order of generations; and
making an identification data stored for identifying a generation of the backup data at a storage position right in front of the by-generation backup data in the storage medium.

9. A data management apparatus for performing a hierarchical storage management by using a primary storage apparatus and a secondary storage apparatus, comprising:
a primary storage control unit for making the primary storage apparatus store data;
an inspection sign generation unit for generating an inspection sign which confirms a consistency of data between the pre- and post-storing done by the primary storage unit;
a primary read-out process unit for reading out data being stored in the primary storage apparatus thereof; and
a secondary storage control unit for making the secondary storage apparatus store the data read out of the primary storage apparatus and the inspection sign.

10. The data management apparatus in claim 9, further comprising:
a secondary read-out process unit for reading out said data stored in said secondary storage apparatus and, additionally, said inspection sign relating to the aforementioned data, wherein
said primary storage control unit confirms a consistency of the data based on the inspection sign read out by the secondary read-out process unit.

11. A data management apparatus for performing a hierarchical storage management by using a primary storage apparatus and a secondary storage apparatus, comprising:
primary storage control means for making the primary storage apparatus store data;
inspection sign generation means for generating an inspection sign which confirms a consistency of data between the pre- and post-storing done by the primary storage means;
primary read-out process means for reading out data being stored in the primary storage apparatus thereof; and
secondary storage control means for making the secondary storage apparatus store the data read out of the primary storage apparatus and the inspection sign.

12. A data management method for performing a hierarchical storage management by using a primary storage apparatus and a secondary storage apparatus, comprising:
generating an inspection sign which confirms a consistency of data between the pre- and post-storing done by the primary storage apparatus;
reading out data stored in the primary storage apparatus thereof; and
making the secondary storage apparatus store the data read out of the primary storage apparatus and the inspection sign.

13. A storage medium being stored with a program for making a computer perform a hierarchical storage management by using a primary storage apparatus and a secondary storage apparatus, wherein, when executed by a computer, the program makes the computer perform the processes of:
generating an inspection sign which confirms a consistency of data between the pre- and post-storing done by the primary storage apparatus;
reading out data stored in the primary storage apparatus thereof; and
making the secondary storage apparatus store the data read out of the primary storage apparatus and the inspection sign.

14. A computer data signal embodied in a carrier wave and representing a program for making a computer perform a hierarchical storage management by using a primary storage apparatus and a secondary storage apparatus, wherein, when executed by a computer, the program makes the computer perform the processes of:
generating an inspection sign which confirms a consistency of data between the pre- and post-storing done by the primary storage apparatus;
reading out data stored in the primary storage apparatus thereof; and
making the secondary storage apparatus store the data read out of the primary storage apparatus and the inspection sign.
